(19) United States
(12) Patent Application Publication
(10) Pub. No.: US 2016/0137489 A1
(43) Pub. Date: May 19, 2016

(54) MICROELECTROMECHANICAL SYSTEMS DEVICE

(71) Applicant: Samsung Electro-Mechanics Co., Ltd., Suwon-si (KR)

(72) Inventors: Jong Woon KIM, Suwon-si (KR); Won HAN, Suwon-si (KR); Woo Seok CHOI, Suwon-si (KR)

(73) Assignee: Samsung Electro-Mechanics Co., Ltd., Suwon-si (KR)

(21) Appl. No.: 14/920,184

(22) Filed: Oct. 22, 2015

(30) Foreign Application Priority Data
Nov. 13, 2014 (KR) 10-2014-0157832

(51) Int. Cl. B81B 7/00

(52) U.S. Cl. CPC B81B 7/0051

(57) ABSTRACT

A microelectromechanical systems (MEMS) device includes: a circuit board; a lower cap disposed on the circuit board; a case disposed on the lower cap and having an internal space; a rotating part rotatably mounted in the case; an upper cap disposed on the case and including a reinforcing part disposed above a axis of the rotating part; and a molding layer encasing the lower cap, the case, and the upper cap.

### CROSS-REFERENCE TO RELATED APPLICATION(S)

This application claims the benefit of Korean Patent Application No. 10-2014-0157832 filed on Nov. 13, 2014, in the Korean Intellectual Property Office, the entire disclosure of which is incorporated herein by reference for all purposes.

### BACKGROUND

1. Field

The following description relates to a microelectromechanical systems (MEMS) device.

2. Description of Related Art

Microelectromechanical systems (MEMS) technology allows for the manufacturing of microelectromechanical structures such as very large scale integrated circuits, sensors, actuators, and the like, by processing a material such as silicon, crystal or glass.

Meanwhile, packages including portions in the vicinity of elements that are molded using plastic have been widely used. However, when excessive stress due to pressure occuring because of the introduction of a molding material is applied to an upper cap of a MEMS device in a molding process, the upper cap of the MEMS device may be damaged.

Therefore, a structure capable of preventing damage to the upper cap of a MEMS device and thinning of the MEMS device is desirable.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a microelectromechanical systems (MEMS) device includes: a circuit board; a lower cap disposed on the circuit board; a case disposed on the lower cap and having an internal space; a rotating part rotatably mounted in the case; an upper cap disposed on the case and including a reinforcing part disposed above a axis of the rotating part; and a molding layer encasing the lower cap, the case, and the upper cap.

The axis may be disposed in a center of an upper end portion of the rotating part, and the reinforcing part may include a rib extending downwardly from a lower surface of the upper cap.

The upper cap may include a protrusion part extending inwardly of the case from an edge of a lower surface of the upper cap.

The protrusion part may include an extended surface disposed in parallel with an upper surface of the case, and an inclined surface inclined from the extended surface.

The inclined surface of the protrusion part may be configured to contact an edge of the rotating part.

The lower cap may include a lower inclined surface configured to prevent contact with the rotating part.

A cross section of the reinforcing part may have a trapezoidal shape.

The rotating part may be configured to rotate around the axis and may have a rectangular shape when viewed from a front of the MEMS device.

The MEMS device may further include a semiconductor element mounted on the circuit board, wherein the lower cap is disposed on the semiconductor element.

According to another general aspect, a MEMS device includes: a circuit board; a lower cap disposed on the circuit board; a case disposed on the lower cap and having an internal space; a rotating part rotatably mounted in the case; an upper cap disposed on the case and configured to shield an upper portion of the case; and a molding layer disposed on the circuit board and encasing the lower cap, the case, and the upper cap therein, wherein the upper cap includes a reinforcing part disposed above a axis of the rotating part and in parallel with the axis, and a protrusion part protruding from an edge of a lower surface of the upper cap to limit rotation of the rotating part.

The protrusion part may include an inclined surface configured to contact an edge of the rotating part.

The MEMS device may include a semiconductor element mounted on the circuit board, wherein the lower cap is disposed on the semiconductor element.

According to another general aspect, a microelectromechanical systems (MEMS) device includes: a circuit board; a case disposed on the circuit board; a rotating part rotatably mounted in the case; an upper cap disposed on the case and comprising a reinforcing part disposed above a axis of the rotating part; and a molding layer encasing the case and the upper cap.

The upper cap may be configured to function as a stopper to limit rotation of the rotating part.

Other features and aspects will be apparent from the following detailed description, the drawings, and the claims.

### BRIEF DESCRIPTION OF THE DRAWINGS

FIG. 1 is a schematic diagram illustrating an example of a microelectromechanical systems (MEMS) device.

FIG. 2 is a view illustrating operation of the MEMS device of FIG. 1, according to an example.

FIG. 3 is a bottom view illustrating a axis of a rotating part of the MEMS device of FIG. 1, according to an example.

FIG. 4 is a schematic diagram illustrating another example of a MEMS device.

FIG. 5 is a view illustrating operation of the MEMS device of FIG. 4, according to an example.

FIG. 6 is a schematic diagram illustrating another example of a MEMS device.

FIG. 7 is a view illustrating operation of the MEMS device of FIG. 6, according to an example.

FIG. 8 is a schematic diagram illustrating another example of a MEMS device.

FIG. 9 is a view illustrating operation of the MEMS device of FIG. 8, according to an example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

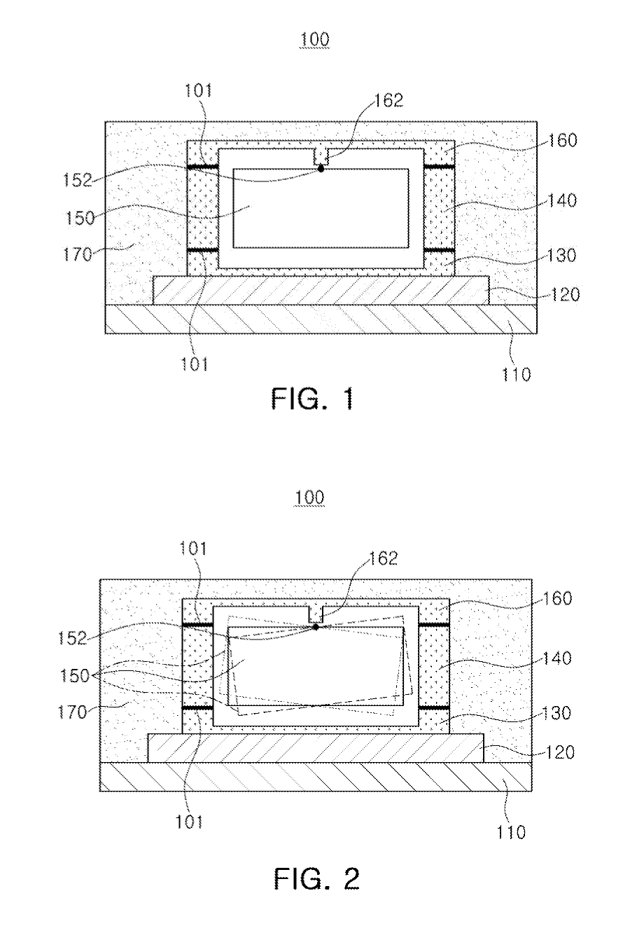

Referring to FIGS. 1 and 2, a microelectromechanical systems (MEMS) device 100, according to an example, includes a circuit board 110, a semiconductor element 120, a lower cap 130, a case 140, a rotating part 150, an upper cap 160, and a molding layer 170.

The semiconductor element 120 is mounted on the circuit board 110. The circuit board 110 may serve as an interconnector receiving an electrical signal from an external control circuit (not illustrated) and transferring the electrical signal to the semiconductor element 120. To this end, the circuit board 110 may have a size larger than that of the semiconductor element 120. The semiconductor element 120 may be, for example, an application specific integrated circuit (ASIC) chip.

The lower cap 130 is disposed on the semiconductor element 120 and has a box shape of which an upper portion is open. That is, the lower cap 130 has a lower surface seated and installed on the semiconductor element 120 and has a box shape having an internal space.

The case 140 is disposed on the lower cap 130 and has an internal space. That is, the case 140 is attached to the lower cap 130 and has a box shape of which upper and lower end portions are open. For example, the case 140 and the lower cap 130 may be bonded to each other by a bonding layer 101.

The case 140 includes an installation rib (not shown) on which a axis 152 of the rotating part 150 is installed. The installation rib may be disposed at an upper end portion of the case 140.

The rotating part 150 is installed in the case 140 and is rotatable around the axis 152. The rotating part 150 may have a substantially rectangular parallelepiped shape. That is, the rotating part 150 may have a rectangular shape when viewed from the front. In addition, the rotating part 150 rotates in the internal space formed by the lower cap 130, the case 140, and the upper cap 160.

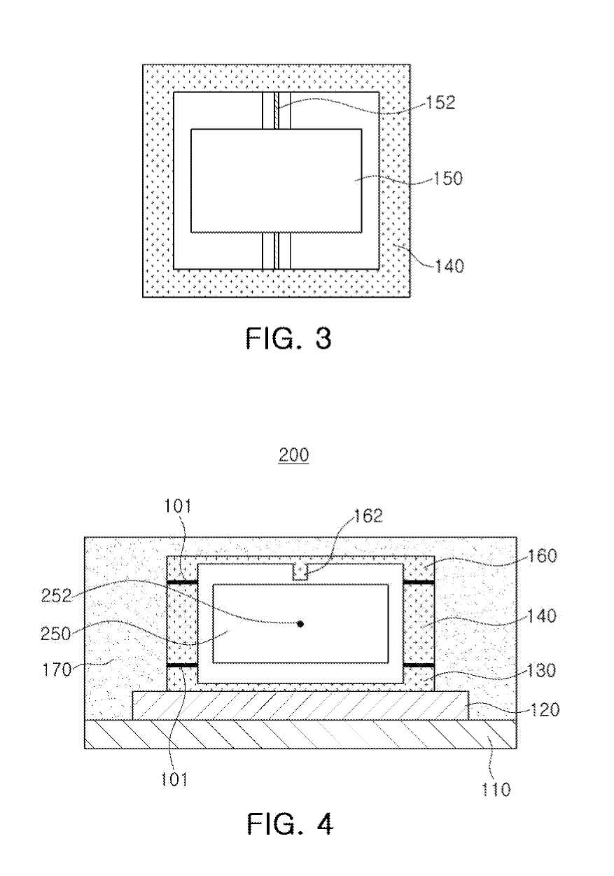

The upper cap 160 is disposed on the case 140 and includes a reinforcing part 162 disposed above the axis 152, as shown in FIGS. 2 and 3. The upper cap 160 may also be bonded to the case 140 by a bonding layer 101. In addition, the reinforcing part 162 protrudes from a lower surface of the upper cap 160 and may be formed to be parallel to the axis 152. That is, the reinforcing part 162 may be formed of a rib extending downwardly from the lower surface of the upper cap 160.

In addition, a cross section of the reinforcing part 162 may have a rectangular shape.

Since the reinforcing part 162 is formed in the upper cap 160 as described above, when a molding material is introduced in order to form the molding layer 170, even in the case that stress is applied to the upper cap 160 due to introduction pressure of the molding material, damage to the upper cap 160 may be prevented.

In more detail, in order to form the molding layer 170, the circuit board 110, on which the semiconductor element 120 is mounted, is installed in a mold and a molding material, such as a synthetic resin, may be introduced into the mold.

Outer surfaces of the lower cap 130, the case 140, and the upper cap 160 may be pressed by the introduced molding material 170. Without the reinforcing part 162 being formed in the upper cap 160, a central portion of the upper cap 160 could be deformed, such that the upper cap 160 and the axis 152 of the rotating part 150 would contact each other. If the upper cap 160 were to deform as described above, the rotating part 150 would not operate normally.

However, since the reinforcing part 162 is formed in the upper cap 160 as described above, deformation of the upper cap 160, damage to the upper cap 160 and interference with the operation of the rotating part 150 due to the introduction of the molding material may be prevented.

In addition, even if a thickness of the upper cap 160 is decreased in order to make MEMS device 100 thinner, since the reinforcing part 162 is formed in the upper cap 160, the deformation of the upper cap and damage to the upper cap 160 may be prevented.

Further, since the reinforcing part 162 is formed in the upper cap 160 and disposed in parallel with the axis 152, interference between the reinforcing part 162 and the rotating part 150 during rotation of the rotating part 150 may be prevented, as illustrated in FIG. 2.

The molding layer 170 is disposed on the circuit board 110 so that the lower cap 130, the case 140, and the upper cap 160 are embedded therein. Therefore, even though an external impact is applied to the lower cap 130, the case 140, and the upper cap 160, the lower cap 130, the case 140, and the upper cap 160 may be protected by the molding layer 170.

The molding layer 170 may be formed of a synthetic resin, for example.

As described above, the damage to the upper cap 160 may be decreased through the reinforcing part 160, such that the MEMS device 100 may be made thinner.

Meanwhile, although a case in which the semiconductor element 120 is mounted on the circuit board 110 has been described above, the semiconductor element 120 is not limited to being mounted as described above, but may be omitted. That is, the lower cap 130 may also be mounted directly on the circuit board 110.

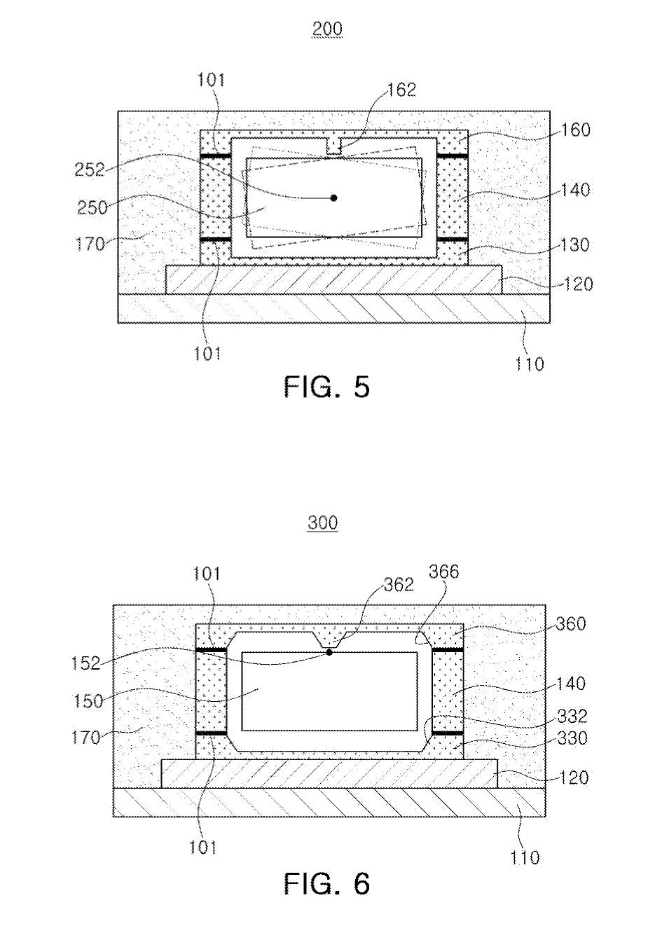

A MEMS device 200 according to another example is shown in FIGS. 4 and 5. Detailed descriptions of the components in FIGS. 4 and 5 that are the same as above-mentioned components in FIGS. 1-3 will be omitted.

FIG. 4 is a schematic diagram illustrating the MEMS device 200.

Referring to FIG. 4, in the MEMS device 200, a axis 252 of a rotating part 250 is disposed in a central portion of the case 140.

The upper cap 160 is disposed on the case 140 and includes the reinforcing part 162 disposed above the axis 252 and the rotating part 250.

The upper cap 160 may be bonded to the case 140 by a bonding layer 101. In addition, the reinforcing part 162 protrudes from a lower surface of the upper cap 160 and is formed to be parallel to the axis 252. That is, the reinforcing part 162 may be formed of a rib extending downwardly from the lower surface of the upper cap 160.

In addition, a cross section of the reinforcing part 162 may have a rectangular shape.

Since the reinforcing part 162 is formed in the upper cap 160 as described above, when a molding material is introduced in order to form the molding layer 170, even though stress due to introduction pressure of the molding material is applied to the upper cap 160, damage to the upper cap 160 may be prevented.

In greater detail, in order to form the molding layer 170, the circuit board 110, on which the semiconductor element 120 is mounted, is installed in a mold and a molding material, which may be a synthetic resin, may be introduced into the mold.

In this case, outer surfaces of the lower cap 130, the case 140, and the upper cap 160 are pressed by the introduced molding material. If the reinforcing part 162 were not formed in the upper cap 160, a central portion of the upper cap 160 could be deformed, such that the upper cap 160 and the rotating part 250 would contact each other. If deformation of the upper cap 160 were to occur as described above, the rotating part 250 could not operate normally.

However, since the reinforcing part 162 is formed in the upper cap 160 as described above, deformation of the upper cap 160 and damage to the upper cap 160 due to the introduction of the molding material may be prevented.

Further, since the reinforcing part 162 is formed in the upper cap 160 and disposed in parallel with the axis 252, interference between the reinforcing part 162 and the rotating part 250 may be prevented during rotation of the rotating part 250, as illustrated in FIG. 5.

As described above, damage to the upper cap 160 may be decreased through the reinforcing part 160, such that the MEMS device 200 may be made thinner.

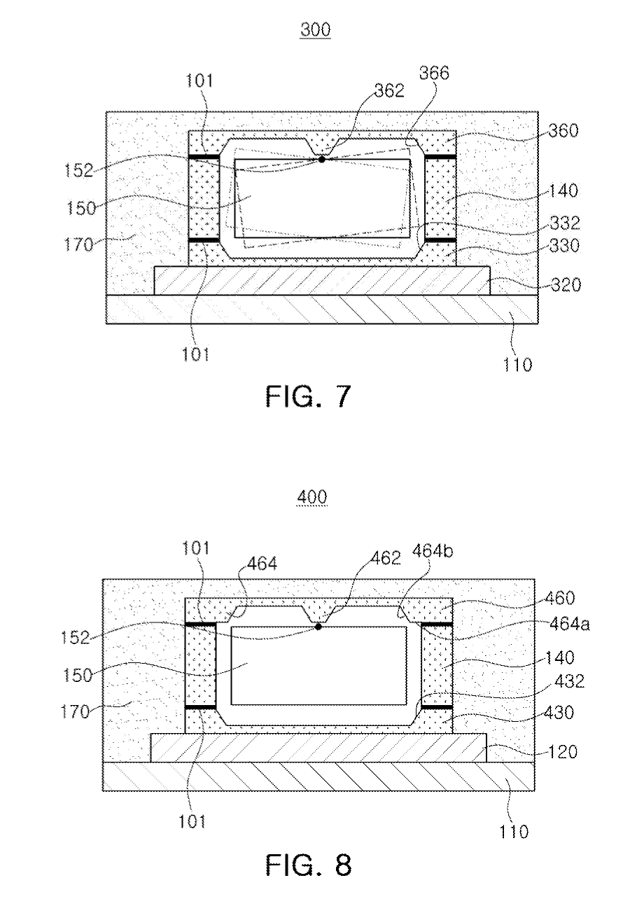

A MEMS device 300 according to another example is illustrated in FIGS. 6 and 7. Detailed descriptions of components that are the same as above-mentioned components of the preceding examples will be omitted.

FIG. 6 is a schematic diagram illustrating the MEMS device 300, and FIG. 7 is a view illustrating operation of the MEMS device 300.

Referring to FIGS. 6 and 7, the MEMS device 300 includes a lower cap 330 and an upper cap 360.

The lower cap 330 includes a lower inclined surface 332 formed at an edge of an inner surface thereof. That is, the lower inclined surface 332 is upwardly inclined from a central portion of the lower cap 330 toward an outer edge of the lower cap 330. In addition, the lower inclined surface 332, which is provided to increase an internal space of the lower cap 330, may be used to improve impact resistance at a time of abnormal movement of the rotating part 150 due to an external impact.

A reinforcing part 362 of the upper cap 360 has a shape that is different from that of the reinforcing part 162 of the MEMS device 100 described above. The reinforcing part 362 of the upper cap 360 has a cross section having an approximately trapezoidal shape, and a side of the reinforcing part 362 that is proximate to the axis 152 has a length that is shorter than that of a side of the reinforcing part that is distant from the axis 152.

However, the reinforcing part 362 is not limited to having the above-mentioned shape, but may have any shape by which interference with the rotating part 150 may be prevented and strength of the upper cap 360 may be increased.

As described above, a thickness of the reinforcing part 362 may be increased, such that strength of the reinforcing part 362 may be increased and the interference between the reinforcing part 362 and the rotating part 150 may be prevented.

Further, the upper cap 360 includes an upper inclined surface 366 formed at an edge of an inner surface thereof. That is, the upper inclined surface 366 is downwardly inclined from a central portion of the upper cap 360 toward an outer side of the upper cap 360. In addition, the upper inclined surface 366 of the upper cap 360 also serves to increase the internal space of the upper cap 360 and improve impact resistance at a time of the abnormal movement of the rotating part 150 due to an external impact.

As described above, even though outer surfaces of the lower cap 330, the case 140, and the upper cap 360 have pressure applied thereto by the introduction of molding material, since the reinforcing part 362 is formed in the upper cap 360, damage to the upper cap 360 due to the introduction of the molding material may be prevented.

Further, since the lower inclined surface 332 and the upper inclined surface 366 are formed in the lower cap 330 and the upper cap 360, respectively, the internal space may be increased such that the rotating part 150 may be more stably driven.

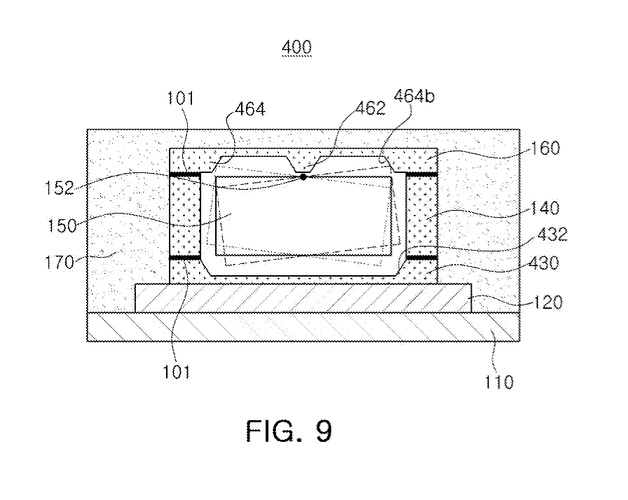

FIG. 8 is a schematic diagram illustrating a MEMS device 400 according to another example. FIG. 9 is a view illustrating operation of the MEMS device 400.

Referring to FIGS. 8 and 9, the MEMS device 400 includes a lower cap 430 and an upper cap 460.

In addition, since the circuit board 110, the semiconductor element 120, the case 140, the rotating part 150, and the molding layer 170 are the same components as the components of the MEMS device 100, detailed descriptions thereof will be omitted.

The lower cap 430 is disposed on the semiconductor element 120 and has a box shape of which an upper portion is open. That is, the lower cap 430 includes a lower surface seated and installed on the semiconductor element 120 and has a box shape having an internal space. Further, the lower cap 430 has a lower inclined surface 432 formed to prevent contact with the rotating part 150.

The upper cap 460 is disposed on the case 140 and includes a reinforcing part 462 disposed above the axis 152.

The upper cap 460 may be bonded to the case 140 by a bonding layer 101. In addition, the reinforcing part 462 protrudes from a lower surface of the upper cap 460 and is formed to be parallel to the axis 152. That is, the reinforcing part 462 is formed of a rib extending downwardly from the lower surface of the upper cap 460. In addition, a cross section of the reinforcing part 462 has a trapezoidal shape.

Since the reinforcing part 462 is formed in the upper cap 460 as described above, when a molding material is introduced in order to form the molding layer 170, even though stress caused by introduction pressure of the molding material is applied to the upper cap 460, damage to the upper cap 460 may be prevented.

In greater detail, in order to form the molding layer 170, the circuit board 110 on which the semiconductor element 120 is mounted is installed in a mold and a molding material, such as a synthetic resin, is introduced into the mold. In this case, outer surfaces of the lower cap 430, the case 140, and the upper cap 460 are pressed by the introduced molding material. If the reinforcing part 462 were not formed in the upper cap 460, a central portion of the upper cap 460 could be deformed, such that the upper cap 460 and the axis 152 of the rotating part 150 could contact each other. If deformation of the upper cap 460 were to occur as described above, the rotating part 150 could not be operated normally.

However, since the reinforcing part 462 is formed in the upper cap 460 as described above, the damage to the upper cap 460 due to the introduction of the molding material may be prevented.

In addition, even though a thickness of the upper cap 460 may be decreased in order to make the MEMS device 400 thinner, since the reinforcing part 462 is formed in the upper cap 460, damage to the upper cap 460 may be prevented.

Further, since the reinforcing part 462 is formed in the upper cap 460 and is disposed in parallel with the axis 452, interference between the reinforcing part 462 and the rotating part 150 at the time of rotation of the rotating part 150 may be prevented, as illustrated in FIG. 9.

The upper cap 460 includes a protrusion part 464 extending inwardly of the case 140 from an edge of the lower surface of the upper cap 460. The protrusion part 464 includes an extended surface 464a disposed in parallel with an upper surface of the case 140, and an inclined surface 464b inclined from the extended surface 464a. The protrusion part 464 protrudes so that an edge of the rotating part 150 contacts the inclined surface 464b during extreme rotation of the rotating part 150. The protrusion part 464 therefore acts as a stopper to limit rotation of the rotating part 150.

As described above, since the protrusion part 464 serving as a stopper is formed in the upper cap 460, in a case in which the rotating part 150 abnormally rotates due to an external impact, the edge of the rotating part 150 may contact the protrusion part 464, as illustrated in FIG. 9, such that impact resistance may be improved.

Further, since the protrusion part 464 is formed in the upper cap 460, strength of the edge of the upper cap 460 may be improved.

As described above, the strength of the upper cap 460 and resistance to external impacts may be improved through the reinforcing part 462 and the protrusion part 464 of the upper cap 460.

As set forth above, according to the examples disclosed herein, damage to the upper cap of a MEMS device may be prevented.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A microelectromechanical systems (MEMS) device comprising:
a circuit board;
a lower cap disposed on the circuit board;
a case disposed on the lower cap and having an internal space;
a rotating part rotatably mounted in the case;
an upper cap disposed on the case and comprising a reinforcing part disposed above a axis of the rotating part; and
a molding layer encasing the lower cap, the case, and the upper cap.

2. The MEMS device of claim 1, wherein the axis is disposed in a center of an upper end portion of the rotating part, and
the reinforcing part comprises a rib extending downwardly from a lower surface of the upper cap.

3. The MEMS device of claim 1, wherein the upper cap comprises a protrusion part extending inwardly of the case from an edge of a lower surface of the upper cap.

4. The MEMS device of claim 3, wherein the protrusion part comprises an extended surface disposed in parallel with an upper surface of the case, and an inclined surface inclined from the extended surface.

5. The MEMS device of claim 4, wherein the inclined surface of the protrusion part is configured to contact an edge of the rotating part.

6. The MEMS device of claim 1, wherein the lower cap comprises a lower inclined surface configured to prevent contact with the rotating part.

7. The MEMS device of claim 1, wherein a cross section of the reinforcing part has a trapezoidal shape.

8. The MEMS device of claim 1, wherein the rotating part is configured to rotate around the axis and has a rectangular shape when viewed from a front of the MEMS device.

9. The MEMS device of claim 1, further comprising a semiconductor element mounted on the circuit board, wherein the lower cap is disposed on the semiconductor element.

10. A MEMS device comprising:
a circuit board;
a lower cap disposed on the circuit board;
a case disposed on the lower cap and having an internal space;
a rotating part rotatably mounted in the case;
an upper cap disposed on the case and configured to shield an upper portion of the case; and
a molding layer disposed on the circuit board and encasing the lower cap, the case, and the upper cap therein,
wherein the upper cap comprises
a reinforcing part disposed above a axis of the rotating part and in parallel with the axis, and
a protrusion part protruding from an edge of a lower surface of the upper cap to limit rotation of the rotating part.

11. The MEMS device of claim 10, wherein the protrusion part comprises an inclined surface configured to contact an edge of the rotating part.

12. The MEMS device of claim 10, further comprising a semiconductor element mounted on the circuit board, wherein the lower cap is disposed on the semiconductor element.

13. A microelectromechanical systems (MEMS) device comprising:
a circuit board;
a case disposed on the circuit board;
a rotating part rotatably mounted in the case;
an upper cap disposed on the case and comprising a reinforcing part disposed above a axis of the rotating part; and
a molding layer encasing the case and the upper cap.

14. The MEMS device of claim 13, wherein the upper cap is configured to function as a stopper to limit rotation of the rotating part.
